(19) United States
(12) Patent Application Publication
(10) Pub. No.: US 2014/0033767 A1
(43) Pub. Date: Feb. 6, 2014

(54) METHOD OF PRODUCING A SOLAR CONCENTRATOR

(71) Applicants: Wolfram Wintzer, Jena (DE); Lars Arnold, Neustadt (DE); Hagen Goldammer, Jena (DE)

(72) Inventors: Wolfram Wintzer, Jena (DE); Lars Arnold, Neustadt (DE); Hagen Goldammer, Jena (DE)

(21) Appl. No.: 14/008,673

(22) PCT Filed: Jan. 26, 2012
(86) PCT No.: PCT/EP12/00339

§ 371 Date: Sep. 30, 2013

(30) Foreign Application Priority Data
Mar. 30, 2011 (DE) 102011015593.7

(51) Int. Cl. C03B 11/07; H01L 31/052

(52) U.S. Cl. CPC C03B 11/07; H01L 31/0522
USPC 65/83; 65/66

(57) ABSTRACT

A method for producing a solar concentrator, the method comprising providing an upper mold, adapted for molding a light exit face, providing a bottom mold, adapted for molding a light entry face, and blank molding the transparent material between the upper mold and the bottom mold to form a solar concentrator comprising a light entry face and a light exit face.

### CROSS-REFERENCE TO RELATED APPLICATIONS

This application is the U.S. national phase of PCT/EP2012/000339 filed Jan. 26, 2012. PCT/EP2012/000339 claims the benefit under the Convention of German Patent Application No. 10 2011 015 593.7 filed Mar. 30, 2011.

### FIELD OF THE INVENTION

The invention concerns a method for manufacturing a solar concentrator having a solid body of transparent material, which solid body comprises a light entry surface (also referred to as light coupling or inlet face e.g. in patent literature) and a light exit surface (also referred to as light decoupling or outlet face e.g. in patent literature). In context with the light entry (coupling) and light exit(decoupling) areas described and outlined in the following specification and claims the term “face”, only, is used for the sake of simplicity and is to include the term and full meaning of “surface” as well).

### BACKGROUND INFORMATION

FIG. 1 shows a known solar concentrator 101 which is depicted in FIG. 2 by way of a cross-sectional representation. The solar concentrator 101 comprises a light entry (or inlet) face 102 and a ground light exit (or outlet) face 103 as well as a light guide conducting) part (or portion) 104 located between the light entry face 102 and the light exit face 103 and tapering in the direction of the light exit face 103. Reference numeral 105 denotes a light guide portion surface which restricts the light guide portion 104 between the light entry face 102 and the light exit face 103. FIG. 3 shows a further known solar concentrator 201, which has been disclosed in the course of a Congress “3^{rd} International Workshop on Concentrating Photovoltaic Power Plants” held in Bremerhaven from 20-22, Oct. 2010.

EP 1 396 035 B1 discloses a solar concentrator module comprising, on its frontal side, a front lens and, on its rear side, a receiver cell, and, between the front lens and the receiver cell, a reflector which has inclined side walls at least along two opposing sides of the receiver cell, and, in the centre of the module, a flat vertical reflector, wherein the sidewall reflectors are shortened such that the ratio between the height H of the concentrator and the focal length F of the lens lies between 0.6 and 0.9.

It is an object of the invention to reduce the costs for the production of solar concentrators. It is a further object of the invention to manufacture solar concentrators of a particularly high quality within restricted budget conditions.

### SUMMARY

The aforementioned object is achieved by a method for producing a solar concentrator from transparent material, wherein the solar concentrator comprises a light entry (inlet) face, a light exit (outlet) face and, in particular, a light passage (guide or conducting) portion located between the light entry face and the light exit face and in particular tapering in the direction of the light entry face, which light passage (guide) portion is restricted by a light passage (guide or conducting) portion surface between the light entry face and the light exit face, and wherein, between an upper mold, adapted/configured for molding/forming the light exit face, and a bottom mold adapted/configured for molding/forming the light entry face, the transparent material is blank molded to form the solar concentrator. Herein, it is particularly provided for that the light entry face and the light exit face be blank molded.

In the sense of the invention, a solar concentrator is, in particular, a secondary concentrator. In the sense of the invention, a solid body is, in particular, monolithic.

In the sense of the invention, transparent material is particularly glass. In the sense of the invention, transparent material is, in particular, silicate glass. In the sense of the invention, transparent material is, in particular, glass as described in Document WO2009/109209 A1. In the sense of the invention, glass particularly comprises
0.2 to 2% by weight Al₂O₃,
0.1 to 1% by weight Li₂O,
0.3, in particular 0.4 to 1.5% by weight Sb₂O₃,
60 to 75% by weight SiO₂,
3 to 12% by weight Na₂O,
3 to 12% by weight K₂O, and/or
3 to 12% by weight CaO.

A light passage (guide or conducting) portion (or section) (in the following, only the term “light passage portion” will be used in context with this component through which light is guided to pass from entry to exit; throughout the following specification and claims to include any portion, section or similar object functioning in said manner of guided passage) taken in the sense of the invention, extends along the optical axis of the solar concentrator, in particular over a length which is larger than the diameter of the light exit face and/or of the solar concentrator. A light passage (guide) portion (or section) surface, taken in the sense of the invention, is, in particular, inclined relative to the optical axis of the solar concentrator. An optical axis of the solar concentrator is, in particular, an orthogonal or the orthogonal, respectively, of the light exit face. The light passage portion surface may be coated.

In the sense of the invention, the term blank molding is, in particular, to be understood in a manner that an optically operative or effective) surface is to be molded under pressure (injection molded) such that any subsequent (finishing or) post-treatment of the contour of this optically operative surface may be dispensed with or does not apply or will not have to be provided for, respectively. Consequently, it is particularly provided for that, after blank molding, the light exit face is not ground, i.e. it will not have to be treated by grinding.

In an embodiment of the invention, the solar concentrator comprises, arranged between the light entry face and the light exit face, a support (or, as used in some places of the following, “carrier”) frame including an outer edge, wherein the support frame and/or the outer edge is/are blank molded or completely blank molded, respectively, with full/complete mold contact occurring. In the sense of the invention, a support frame may, in particular as well, be a flange. In the sense of the invention, a support frame may, in particular, be configured to extend totally or at least partly circumferentially. In the sense of the invention, a support frame may, in particular, extend beyond the light exit face in the direction of the optical axis of the solar concentrator. In the sense of the invention, an outer edge is, in particular, that part of the solar concentrator which is situated farthest away from the optical axis of the solar concentrator. In the sense of the invention, an outer edge is, in particular, that part of the solar concentrator which has the largest radial extension. In particular, it has been provided for that the support frame extends at least partly beyond the light passage portion in an orthogonal direction relative to the axis of the solar concentrator and/or that the support frame at least partly projects beyond the light passage portion radially with respect to the optical axis of the solar concentrator.

In an embodiment of the invention, a surface of the support frame facing the light entry face is blank molded by means of a first mold part (component) of the bottom mold and by means of a second mold part (component) of the bottom mold. In this context, it is particularly provided for that a step, set-off or pitch is press (injection) molded into the surface of the support frame facing the light exit face, by means of the first mold part and the second mold part. The pitch extends, in particular, essentially in parallel to the optical axis of the solar concentrator. In an embodiment of the invention, the first mold part, in particular at least partially, in particular, however, completely encloses the second mold part. In an embodiment of the invention the second mold part is configured to be at least two-part. Herein, it may in particular the provided for that it comprises a molding portion/part and a carrier or support portion/part, wherein the support portion will not come into contact with the transparent material. The molding portion and the support portion are, in particular, screwed together. When exerting pressure it is, in particular, provided for that the upper mold and the bottom mold are (positioned with respect to each other and) made to approach each other. In this context, the upper mold may be made to approach the bottom mold and/or the bottom mold may be made to approach the upper mold. The upper mold and the bottom mold are particularly made to approach each other as long until they contact each other or form a closed entire mold, respectively. In an embodiment of the invention, the upper mold contacts the first mold part after the closing movement of the entire mold or while exerting pressure, respectively. The respective mold or the respective molds is/are, for the purpose of injection molding, moved along the optical axis of the solar concentrator or vertically, respectively.

In a further embodiment of the invention, the light exit face is curved convexly. In a further embodiment of the invention, the convex light exit face is curved with a curvature of more than 30 mm. In a further embodiment of the invention, the light exit face is curved such that its (maximum) deviation of contour from the ideal plane or the light exit face, respectively, amounts to less than 100 μm. In the sense of the invention, an ideal plane is, in particular, a plane through the transition of the light passage portion surface into the light exit face. In the sense of the invention, a light exit plane is, in particular, a plane through the transition of the light passage portion surface into the light exit face. In the sense of the invention, a light exit plane is, in particular, a plane parallel to the plane through the transition of the light passage portion surface into the light exit face, when placed through the apex (of the curvature) of the light exit face. In the sense of the invention, a light exit plane is, in particular, a plane orthogonal to the tapering light passage portion when placed through the apex (of the curvature) of the light exit face. In the sense of the invention, a light exit plane is, in particular, a plane orthogonal to the optical axis of the solar concentrator when placed through the apex (of the curvature) of the light exit face. In a further embodiment of the invention, the convex light exit face is curved such that its (maximum) deviation of contour from the ideal plane or from the light exit face, respectively, amounts to more than 1 μm. In a further embodiment of the invention, the light exit face is planar. A planar light entry face or light exit face, respectively, may show a shrinkage-based, in particular concave deviation of contour from an ideal plane, said contour deviation, for example, possibly amounting up to 20 μm or even up to 40 μm.

In an embodiment of the invention, the solar concentrator or the transparent material, respectively, may have a mass of between 2 g and 50 g.

In an embodiment of the invention, the transparent material has a viscosity of no more than 10^{4,5} dPas immediately before (press/injection) molding.

In an embodiment of the invention, prior to said blank molding, the transparent material is drawn into the bottom mold in a liquid state by means of a depression (also defined as low or negative pressure, pressure lower than surrounding pressure, underpressure). In a yet further preferred embodiment of the invention, the depression amounts to at least 0.5 bar. In a yet further preferred embodiment of the invention, the depression corresponds, in particular, to vacuum. In an embodiment of the invention, the depression is generated in a hole of the bottom mold, which hole opens out at the bottom-most place of the surface of the bottom mold provided for molding the light entry face. In an embodiment of the invention, the surface of the bottom mold provided for the molding of the light entry face has at least one hole, each, at those places at which the surface of the bottom mold provided for molding the light entry face shows a local minimum and/or extends horizontally, wherein the depression is generated in the respective holes. In the sense of the invention, a hole provided in the bottom mold is, in particular, a bore.

In an embodiment of the invention, the transparent material is subsequently, however prior to said blank molding, cooled down In the sense of the invention, cooling (down) may occur actively, in particular by feeding a coolant, or passively by waiting until the desired viscosity or temperature, respectively, is obtained as such. Cooling (down) may occur, in particular, by delaying the closing of the entire mold formed by the upper mold and the bottom mold, after the transparent material has been drawn into the second mold in a liquid state by means of the depression. Herein, the delaying, in particular, includes a time interval of at least 0.02 t_{Tg}. The delaying, in particular, includes a time interval of 0.15 t_{Tg}, at the utmost. The delaying or the cooling down, respectively, in particular lasts at least 0.02 t_{Tg}. The delaying or the cooling down, respectively, in particular lasts 0.15 t_{Tg}, at the utmost. Herein, t_{Tg} is the time, which is necessary under the conditions of the respective (active and passive) cooling down, until every region of the transparent material has reached a temperature which is equal to or lies below the transformation temperature T_{g}.

While performing the cooling down action or after cooling down it may be provided for that the surface of the liquid transparent material facing the upper mold is locally heated, for example by a flame.

In an embodiment of the invention, the solar concentrator, after blank molding, is drawn out of the bottom mold by means of a depression (defined as above) generated in the upper mold. In an embodiment of the invention, the solar concentrator is subsequently cooled down in a suspended state. The cooling (down) may occur actively, in particular by feeding a coolant, or passively by waiting until the desired viscosity or temperature, respectively, is reached. The cooling (down) in a suspended state may, in particular, last at least 5 seconds. Thereafter, it is particularly provided for that the solar concentrator be cooled on an appropriate support means on a cooling conveyor or leer, in particular whilst adding heat.

In an embodiment of the invention, the upper mold comprises one or several holes which open/s out in the face of the upper mold provided for molding the carrier frame, wherein the depression generated in the upper mold is generated in the holes. In the sense of the invention, a hole provided in the upper mold is, in particular, a bore.

The aforementioned object is, furthermore, achieved by a method for manufacturing a solar module, wherein an aforementioned solar concentrator is, by its light exit face, connected to a photovoltaic element and/or fixedly aligned with regard to a photovoltaic element.

In an process for generating electric energy, sunlight is made to enter the light entry face of a solar concentrator of an aforementioned solar module.

In an process for generating electric energy, sunlight is made to enter the light entry face of an aforementioned solar concentrator.

The invention particularly makes it possible to reduce shrinkage of the light passage portion or to shift such shrinking to the support/carrier frame, respectively. Moreover, it is possible to achieve a blank molded light exit face as well as a blank molded light entry face even in the case of slight fluctuations of the quantity of the transparent material supplied. By means of the invention it is, in particular, possible to accomplish a solar concentrator in one pressing step/step of injection, only, which, in connection with the high quality of such a solar concentrator leads to a reduction of the expenditure for the production thereof.

Advantages and details will become apparent from the following description of examples of embodiment.

### BRIEF DESCRIPTION OF THE DRAWINGS

FIG. 1 shows a perspective representation of a known solar concentrator;

FIG. 2 shows a cross-sectional representation of the solar concentrator as shown in FIG. 1;

FIG. 3 shows a perspective representation of a further known solar concentrator;

FIG. 4 shows a method for manufacturing a solar concentrator,

FIG. 5 shows an example of an embodiment of a solar concentrator produced in accordance with the present invention,

FIG. 6 shows a perspective representation of the solar concentrator in accordance with FIG. 5 with a view of the light entry face,

FIG. 7 shows a perspective representation of the solar concentrator in accordance with FIG. 5 with a view of the light exit face,

FIG. 8 shows an example of an embodiment of a mold for forming the solar concentrator in accordance with FIG. 5, and

FIG. 9 shows an example of an embodiment of a solar module including a solar concentrator in accordance with FIG. 5.

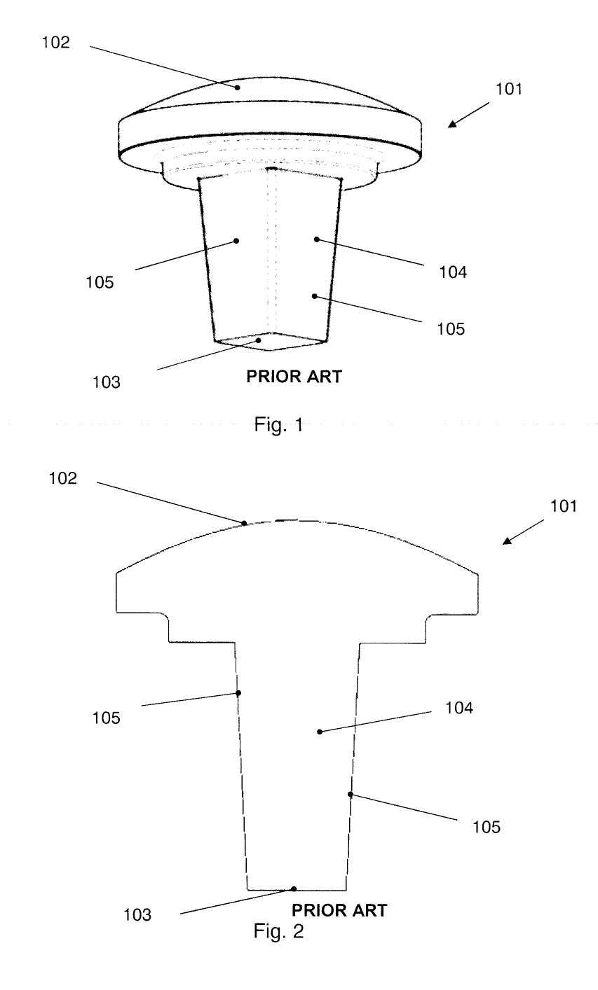

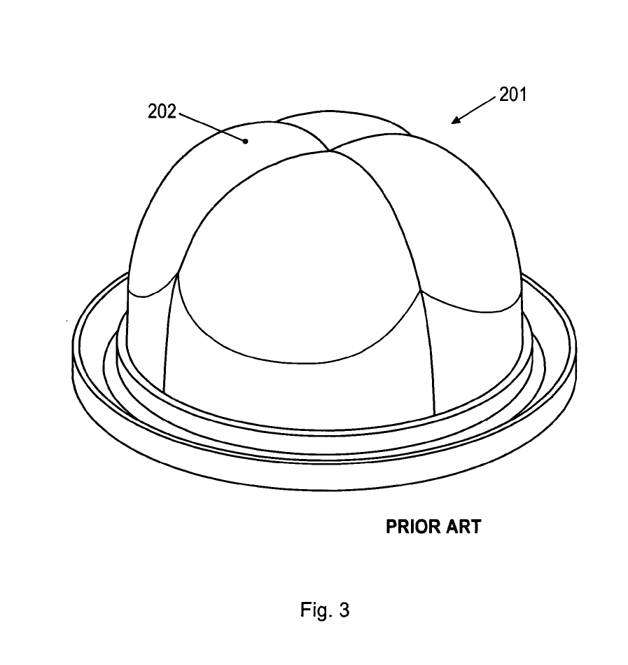

### DETAILED DESCRIPTION

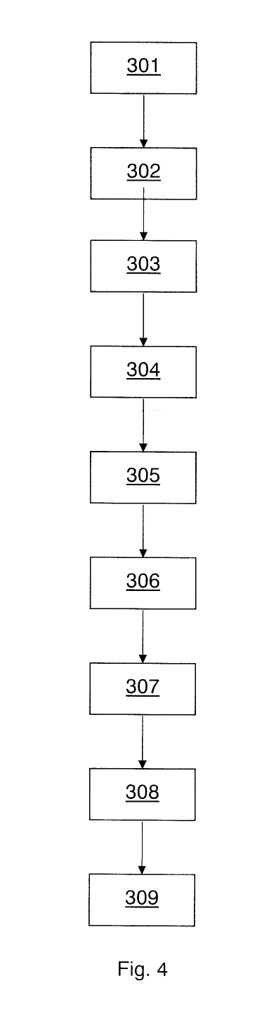

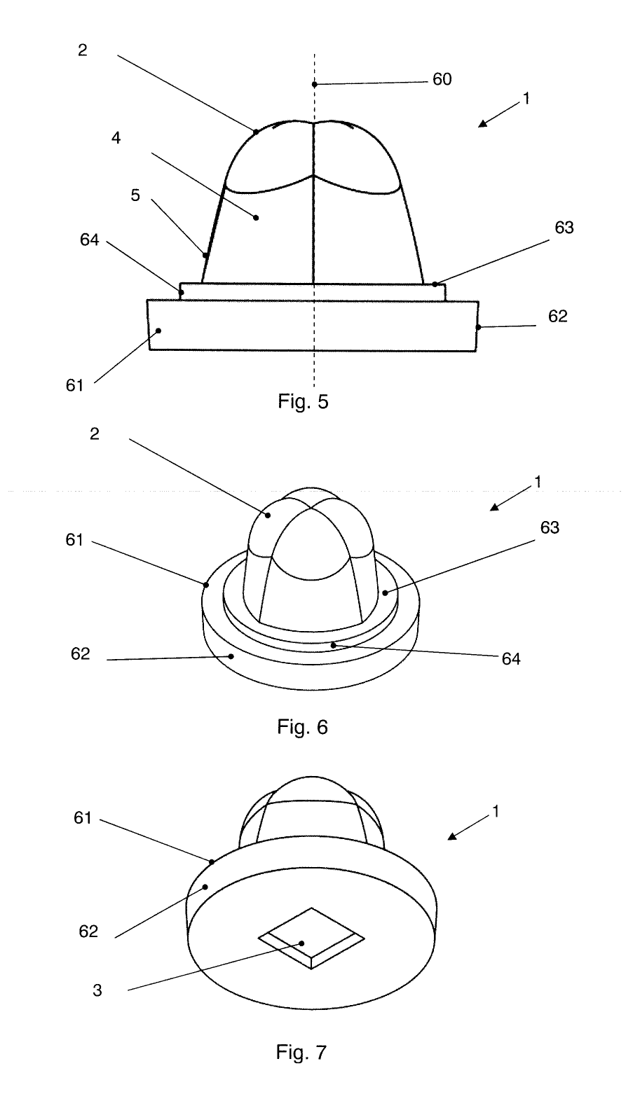

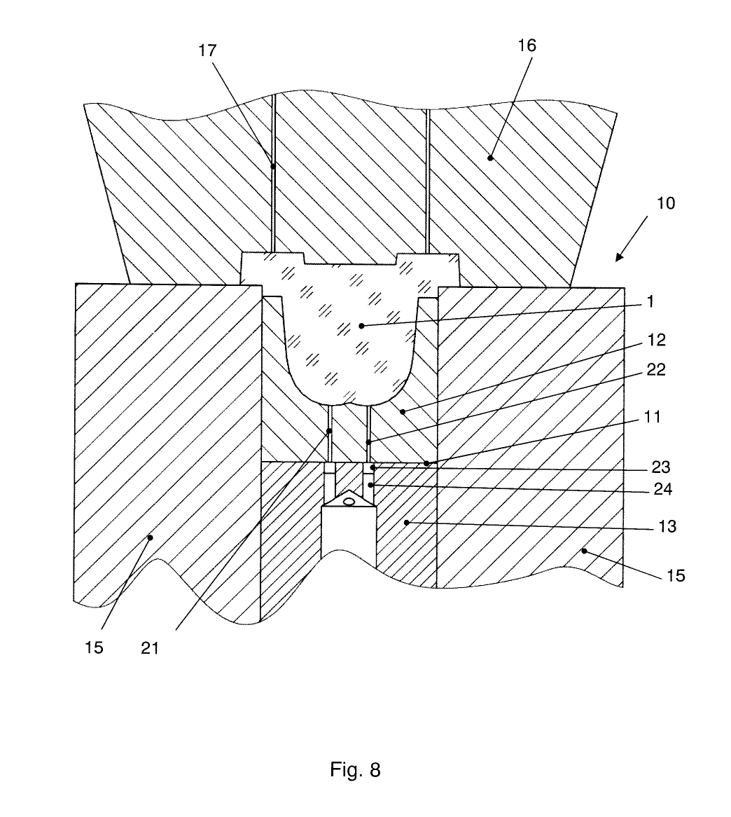

FIG. 4 shows a method or process for manufacturing the solar concentrator 1 according to FIG. 5, FIG. 6, and FIG. 7, with the solar concentrator 1 having been depicted in FIG. 5 by way of a side view, in FIG. 6 by way of a perspective representation from above, and in FIG. 7 by way of a perspective representation from below. The solar concentrator 1 is a monolithic component of glass, comprising
0.2 to 2% by weight Al₂O₃,
0.1 to 1% by weight Li₂O,
0.3, in particular 0.4 to 1.5% by weight Sb₂O₃,
60 to 75% by weight SiO₂,
3 to 12% by weight Na₂O,
3 to 12% by weight K₂O, and
3 to 12% by weight CaO.

The solar concentrator 1 comprises a blank molded light entry face 2 and a blank molded light exit face 3 as well as a light passage (guide) portion 4 located between the light entry face 2 and the light exit face 3 and tapering in the direction of the light entry face 2. Reference numeral 5 designates a light passage (guide) portion surface which restricts the light passage portion 4 between the light entry face 2 or a support frame 61, respectively, and the light exit face 3. The solar concentrator 1 moreover comprises a support frame 61 including a blank molded outer edge 62. Moreover, the support frame 61 has a surface 63 facing the light exit face 3 and including a step, set-off or pitch 64.

The process represented in FIG. 4 starts with procedural stage or step 301, in which a drop of transparent material is cut-off at the outlet of a dispenser. To this end, a bottom mold 10 shown in FIG. 8 is positioned under the outlet so that the drop directly ends up in or falls into, respectively, the bottom mold 10. It may be provided for that the drop is either cut and falls into the bottom mold 10, or that it is received while flowing through the bottom mold 10 to be cut then.

The bottom mold 10 comprises a mold part or mold component 15 and a mold part or mold component 11 for forming the light passage section surface 5 and for forming the light exit face 3, wherein the mold part 15 surrounds or encloses the mold part 11. The mold part 15 is an example of embodiment of a first mold part/component taken in the sense of the claims. The mold part 11 is an example of embodiment of a second mold part/component taken in the sense of the claims. The partial mold 11 comprises a molding partial: component 12 and a carrier or support 13, with which the molding partial component 12 is screwed together. The molding partial component 12 or the partial mold 11, respectively, includes, in the surface provided for molding the light entry face 2, at least one bore 21 or 22, respectively, arranged at positions at which the surface of the bottom mold provided for molding the light entry face 2 has a local minimum or extends horizontally, respectively. The bores 21 and 22 open out into a circumferential channel 23 of the carrier part 13, in which a depression (as defined above: low or negative pressure, pressure lower than surrounding pressure, underpressure) can be generated via bores 24, which depression generates a depression in the bores 21 and 22.

Step 301 is followed by step 302 in which the depression is generated in the bores 21 and 22 so that the transparent material is drawn or sucked into the bottom mold 10. A step 303 follows, in which the liquid material is cooled down for a period of between 0.02 t_{Tg} and 0.15 t_{Tg}, wherein t_{Tg} is the time which, under the conditions of active and passive cooling (down), is necessary until every region of the transparent material has reached a temperature equal to or lying below the transformation temperature T_{g}. In the course of steps 302 and 303 or thereafter the bottom mold 10 is positioned in a pressing (injecting) apparatus. An optional step 304 follows during which a surface of the transparent material facing an upper mold 16, which surface, after pressing (pressure injection), forms the light exit face 3, is heated, e.g. by fire or flame polishing.

A step 305 follows, in which the transparent material is blank molded between the bottom mold 10 and an upper mold designated by reference numeral 16, into the solar concentrator 1. Herein, it is provided for that the outer edge or flange 62 of the support frame 61 is blank molded with complete mold contact. The upper mold 16 and the mold part 15 are brought into contact with each other. The step 64 is formed by means of a set-off between the mold part/component 15 and the mold part/component 11.

A step 306 follows, in which the mold formed by the bottom mold 10 and the upper mold 16 is opened. To this end, the upper mold 16, for example, is moved upwardly. The upper mold 16 has bores designated by reference numeral 17, which open out into the surface of the upper mold 16, which surface is provided for forming the carrier frame 61. It is provided for that a depression is generated within the bores 17 so that the readily and completely pressed solar concentrator 1, together with the upper mold 16, is moved out of the bottom mold 10. It may be provided for subsequently that certain regions of the solar concentrator 1 are blown with cooling air. Alternatively or additionally it may be provided for that the light passage section surface 5 is heated.

There is provided an optional step 307, in which the solar concentrator 1 is hot-coated. Moreover, an optical/visual inspection of the solar concentrator 1 is provided for by means of an optional step 308. A step 309 follows, in which the solar concentrator 1 is delivered to a leer (cooling path) and is selectively cooled down herein (by adding heat).

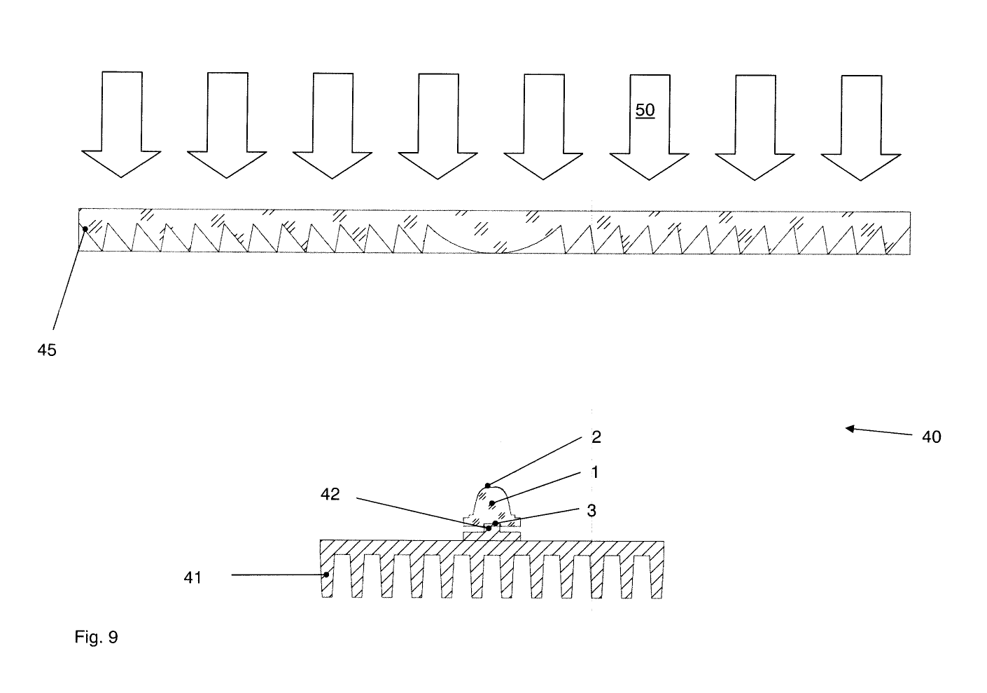

FIG. 9 shows an example of embodiment of a solar module 40 including a solar concentrator 1 manufactured according to the invention. The solar module 40 comprises a heat sink (cooling body or cooling element) 41, on which a photovoltaic element 42 is arranged. The light exit face 3 is connected to the photovoltaic element 42 by means of an adhesive layer. A retention means may be provided which engages the carrier frame 61. The solar module 40 moreover comprises a primary solar concentrator 45 designed as a Fresnel lens for directing sunlight 50 onto the light entry face 2 of the solar concentrator 1, the latter arranged or configured or provided, respectively, as a secondary solar concentrator. The sunlight induced into or made to enter the solar concentrator 1 via the light entry face 2 exits via the light exit face 3 of the solar concentrator 1 and makes impact with or impinges the photovoltaic element 42.

Elements, dimensions and angles as used in FIGS. 4 to 9, respectively, have been drafted in consideration of simplicity and clarity and not necessarily to scale. For example, the orders of magnitude of some of the elements, dimensions and angles, respectively, have been exaggerated with regard to other elements, dimensions and angles, respectively, in order to enhance comprehension of the examples of embodiment of the present invention.

1.-10. (canceled)

11. A method for producing a solar concentrator, the method comprising:
providing an upper mold, adapted for molding a light exit face;
providing a bottom mold, adapted for molding a light entry face;
drawing a transparent material in a liquid state into the bottom mold by means of a depression; and
blank molding the transparent material between the upper mold and the bottom mold to form a solar concentrator comprising a light entry face, a light exit face and a light passage portion located between the light entry face and the light exit face, which light passage portion is restricted by a light passage portion surface between the light entry face and the light exit face.

12. The method as claimed in claim 11, wherein the depression is below 0.5 bar.

13. The method as claimed in claim 11, wherein the depression is generated in a hole of the bottom mold, which hole opens out at the bottom-most position of the surface of the bottom mold.

14. The method as claimed in claim 11, wherein the surface of the bottom mold has at least one hole, each, at those positions at which the surface of the bottom mold has a local minimum, wherein the depression is generated in the respective holes.

15. The method as claimed in claim 11, wherein the surface of the bottom mold has at least one hole, each, at those positions at which the bottom surface of the bottom mold extends horizontally, wherein the depression is generated in the respective holes.

16. The method as claimed in claim 15, the method further comprising:
withdrawing the solar concentrator after blank molding from the bottom mold by means of a depression generated in the upper mold.

17. The method as claimed in claim 16, the method further comprising:
subsequently cooling the solar generator in a suspended state.

18. The method as claimed in claim 15, the method further comprising:
withdrawing the solar concentrator after blank molding from the bottom mold by means of a depression generated in the upper mold, wherein the upper mold comprises holes which open out in a surface of the upper mold configured for molding a flange of the solar concentrator, wherein the depression generated in the upper mold is generated in the holes.

19. The method as claimed in claim 11, the method further comprising:
withdrawing the solar concentrator after blank molding from the bottom mold by means of a depression generated in the upper mold.

20. The method as claimed in claim 19, the method further comprising:
subsequently cooling the solar generator in a suspended state.

21. The method as claimed in claim 11, the method further comprising:
withdrawing the solar concentrator after blank molding from the bottom mold by means of a depression generated in the upper mold, wherein the upper mold comprises holes which open out in a surface of the upper mold configured for molding a flange of the solar concentrator, wherein the depression generated in the upper mold is generated in the holes.

22. A method for producing a solar concentrator, the method comprising:
providing an upper mold, adapted for molding a light exit face;
providing a bottom mold, adapted for molding a light entry face; and
blank molding a transparent material between the upper mold and the bottom mold to form a solar concentrator comprising a light entry face, a light exit face and a light passage portion located between the light entry face and the light exit face, which light passage portion tapering in the direction of the light entry face and being restricted by a light passage portion surface between the light entry face and the light exit face.

23. The method as claimed in claim 22, the method further comprising:
withdrawing the solar concentrator after blank molding from the bottom mold by means of a depression generated in the upper mold.

24. The method as claimed in claim 23, the method further comprising:
subsequently cooling the solar generator in a suspended state.

25. The method as claimed in claim 22, the method further comprising:
withdrawing the solar concentrator after blank molding from the bottom mold by means of a depression generated in the upper mold, wherein the upper mold comprises holes which open out in a surface of the upper mold configured for molding a flange of the solar concentrator, wherein the depression generated in the upper mold is generated in the holes.
